(19) United States
(12) Patent Application Publication
(10) Pub. No.: US 2026/0358382 A1
(43) Pub. Date: Nov. 12, 2026

(54) ISOLATED VOLTAGE MEASUREMENT VIA FREQUENCY CONVERSION

(71) Applicant: Haier US Appliance Solutions, Inc., Wilmington, DE (US)

(72) Inventors: Mark Anthony Didat, Floyds Knobs, IN (US); Steven Michael Recio, Louisville, KY (US)

(21) Appl. No.: 19/199,446

(22) Filed: May 6, 2025

(51) Int. Cl. G01R 19/165; G01R 15/18; G01R 19/22; G01R 22/06

(52) U.S. Cl. CPC G01R 19/16547; G01R 15/18; G01R 19/22; G01R 22/06

(57) ABSTRACT

A power supply system for an appliance is provided. The power supply system includes a switching circuit electrically coupled to an alternating current (AC) power supply, the switching circuit configured to determine a line voltage measurement indicative of a line voltage provided by the AC power supply. The power supply system further includes a transformer. The transformer includes a primary winding coupled to the switching circuit. The transformer further includes a secondary winding configured to provide a secondary power signal based at least in part on a primary power signal provided to the primary winding. The switching circuit is configured to control a frequency of the primary power signal provided to the primary winding based at least in part on the line voltage measurement.

### FIELD

Example aspects of the present disclosure relate generally to a power supply system for an appliance, and more specifically to determining and communicating a voltage measurement in a power supply system for an appliance.

### BACKGROUND

In general, domestic appliances such as a refrigerator, a dishwasher, a microwave oven, a cooktop, an oven, a washing machine, a dryer, a water heater, a water filter or purifier, an air conditioner, a space heater, or any other suitable household appliance may include a power supply system. Power supply systems in appliances are generally configured to regulate power provided by an AC power source to deliver electrical energy to components of the appliance.

### SUMMARY

Aspects and advantages of embodiments of the present disclosure will be set forth in part in the following description, or can be learned from the description, or can be learned through practice of the embodiments.

One example aspect of the present disclosure is directed to a power supply system for an appliance. The power supply system includes a switching circuit electrically coupled to an alternating current (AC) power supply, the switching circuit configured to determine a line voltage measurement indicative of a line voltage provided by the AC power supply. The power supply system further includes a transformer. The transformer includes a primary winding coupled to the switching circuit. The transformer further includes a secondary winding configured to provide a secondary power signal based at least in part on a primary power signal provided to the primary winding. The switching circuit is configured to control a frequency of the primary power signal provided to the primary winding based at least in part on the line voltage measurement.

Another example aspect of the present disclosure is directed to a power supply system for an appliance. The power supply system includes a non-isolated side comprising a switching circuit electrically coupled to an alternating current (AC) power supply, the switching circuit configured to determine a line voltage measurement indicative of a line voltage provided by the AC power supply. The power supply system further includes an isolated side electrically isolated from the AC power supply. The power supply system further includes a transformer. The transformer includes a primary winding coupled to the non-isolated side. The transformer further includes a secondary winding configured to provide a secondary power signal to the isolated side based at least in part on a primary power signal provided to the primary winding. The switching circuit is configured to control a frequency of the primary power signal provided to the primary winding based at least in part on the line voltage measurement.

Another example aspect of the present disclosure is directed to a method for communicating a line voltage measurement indicative of a line voltage provided by an alternating current (AC) power supply in an appliance. The method includes determining, by a switching circuit electrically coupled to the AC power supply, the line voltage measurement indicative of the line voltage provided by the AC power supply. The method further includes encoding, by the switching circuit, the line voltage measurement into a primary power signal provided to a primary winding of a transformer via frequency modulation.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 provides a block diagram of an example power supply system according to example embodiments of the present disclosure;

FIG. 2 illustrates a schematic implementation of a power supply system according to example embodiments of the present disclosure; and

FIG. 3 provides an example method for communicating a line voltage measurement according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Some household appliances may include a power supply system configured to receive power from a alternating current (AC) power supply, such as a residential power outlet or other power source. In general, determining electrical characteristics of an AC power supply such as the AC line voltage and estimating the AC power consumption may be challenging. For instance, challenges in determining these electrical characteristics may include powering a dedicated integrated circuit (IC) connected to the AC power supply on the non-isolated side of a power supply system and communicating the measured electrical characteristics to components (e.g., controller, etc.) that may be electrically isolated from the AC power supply on the isolated side of the power supply system.

Some household appliances may utilize a switch mode power supply (SMPS) to provide control power. As such, one aspect of the present disclosure proposes utilizing the SMPS's AC/DC converter (e.g., switching circuit) to measure and communicate an AC line voltage measurement to an electrically isolated controller as a frequency value through the power supply's transformer. The switching circuit, positioned on the non-isolated side of the power supply system, may be directly coupled across the rectifier circuit to determine the AC line voltage measurement. The measured AC line voltage can then be encoded via frequency modulation into the switching circuits operational primary side switching action such that the encoded frequency is induced into the secondary side transformer winding and can be determined (e.g., decoded) by a controller on the isolated side of the power supply system.

Aspects of the present disclosure provide for multiple technical effects and benefits. For instance, a switching circuit connected to the non-isolated side of the power supply system may receive power from the transformer, providing a cost effective solution to some conventional power measurement solutions that use additional, dedicated power supplies. In addition, communicating the measurement via frequency modulation through the isolation transformer may provide a cost effective solution to some conventional designs that use additional, dedicated isolation components for communicating the electrical characteristics of the AC power supply to components (e.g., controller, etc.) on the isolated side of the power supply system.

As used herein, the terms “first,” “second,” and “third” may be used interchangeably to distinguish one component from another and are not intended to signify location or importance of the individual components. The terms “includes” and “including” are intended to be inclusive in a manner similar to the term “comprising.” Similarly, the term “or” is generally intended to be inclusive (e.g., “A or B” is intended to mean “A or B or both”). The term “at least one of” in the context of, e.g., “at least one of A, B, and C” refers to only A, only B, only C, or any combination of A, B, and C. In addition, here and throughout the specification and claims, range limitations may be combined and/or interchanged. Such ranges are identified and include all the sub-ranges contained therein unless context or language indicates otherwise. For example, all ranges disclosed herein are inclusive of the endpoints, and the endpoints are independently combinable with each other. The singular forms “a,” “an,” and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “generally,” “about,” “approximately,” and “substantially,” are not to be limited to the precise value specified. In at least some instances, the approximating language may correspond to the precision of an instrument for measuring the value, or the precision of the methods or machines for constructing or manufacturing the components and/or systems. For example, the approximating language may refer to being within a 10 percent margin, i.e., including values within ten percent greater or less than the stated value. In this regard, for example, when used in the context of an angle or direction, such terms include within ten degrees greater or less than the stated angle or direction, e.g., “generally vertical” includes forming an angle of up to ten degrees in any direction, e.g., clockwise or counterclockwise, with the vertical direction V.

The word “exemplary” is used herein to mean “serving as an example, instance, or illustration.” In addition, references to “an embodiment” or “one embodiment” does not necessarily refer to the same embodiment, although it may. Any implementation described herein as “exemplary” or “an embodiment” is not necessarily to be construed as preferred or advantageous over other implementations. Moreover, each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents.

The terms “coupled,” “fixed,” “attached to,” and the like refer to both direct coupling, fixing, or attaching, as well as indirect coupling, fixing, or attaching through one or more intermediate components or features, unless otherwise specified herein.

Except as explicitly indicated otherwise, recitation of a singular processing element (e.g., “a controller,” “a processor,” “a microprocessor,” etc.) is understood to include more than one processing element. In other words, “a processing element” is generally understood as “one or more processing element.” Furthermore, barring a specific statement to the contrary, any steps or functions recited as being performed by “the processing element” or “said processing element” are generally understood to be capable of being performed by “any one of the one or more processing elements.” Thus, a first step or function performed by “the processing element” may be performed by “any one of the one or more processing elements,” and a second step or function performed by “the processing element” may be performed by “any one of the one or more processing elements and not necessarily by the same one of the one or more processing elements by which the first step or function is performed.” Moreover, it is understood that recitation of “the processing element” or “said processing element” performing a plurality of steps or functions does not require that at least one discrete processing element be capable of performing each one of the plurality of steps or functions.

Referring now to the figures, example aspects of the present disclosure will be discussed in greater detail.

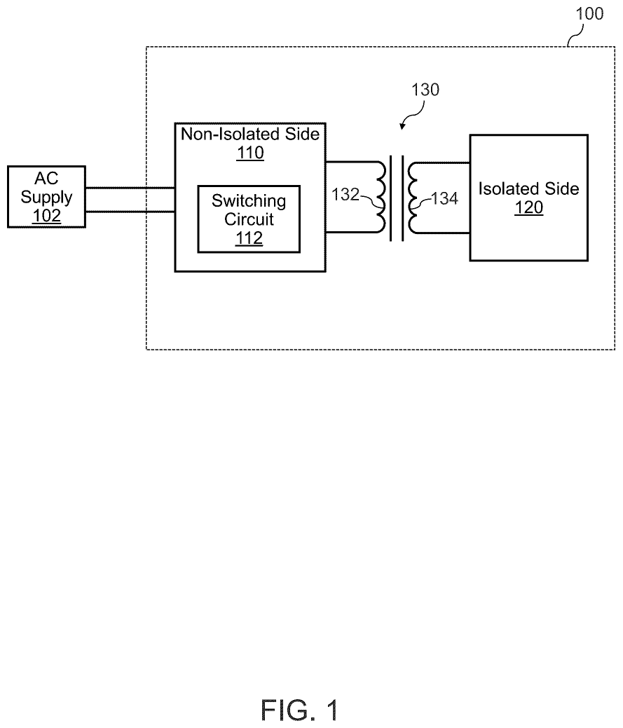

FIG. 1 provides a block diagram of an example power supply system 100 according to example embodiments of the present disclosure. Specifically, power supply system 100 may be a power supply system for an appliance such as a refrigerator, a dishwasher, a microwave oven, a cooktop, an oven, a washing machine, a dryer, a water heater, a water filter or purifier, an air conditioner, a space heater, or any other suitable household appliance.

Power supply system 100 is configured to receive power from a power supply 102, such as a residential power outlet or other power source. For example, power supply 102 may provide conventional 60 Hz, 120-volt or 240-volt alternating current (AC) to power supply system 100.

Power supply system 100 may include a non-isolated side 110 and an isolated side 120. As shown in FIG. 1, non-isolated side 110 of power supply system 100 is electrically coupled to AC power supply 102, while isolated side 120 of power supply system 100 is electrically isolated from the AC power supply 102. For example, power supply system 100 may include one or more circuit isolation components, such as transformer 130, to electrically isolate the non-isolated side 110 from the isolated side 120.

In some embodiments, non-isolated side 110 may be defined as the high voltage side of power supply system 100 while isolated side 120 may be defined as the low voltage side of power supply system 100. For example, transformer 130 may be a step down transformer such that the voltage on the non-isolated side 110 (e.g., high voltage side) is greater than the voltage on the isolated side 120 (e.g., low voltage side).

As shown, transformer 130 may include a primary winding 132 coupled to the non-isolated side 110 and a secondary winding 134 coupled to the isolated side 120. A primary power signal provided to the primary winding 132 may induce a secondary power signal in the secondary winding 134. Thus, the isolated side 120 of power supply system 100 may receive isolated output power from the non-isolated side 110 via transformer 130.

As shown, non-isolated side 110 includes a switching circuit 112 electrically coupled to AC power supply 102. In some embodiments, switching circuit 112 may be electrically coupled to AC power supply 102 via one or more additional circuit components, such as a rectifier circuit. Switching circuit 112 may be configured to control the frequency of the primary power signal provided to the primary windings 132 of transformer 130. For example, the non-isolated side 110 may include a switching device controlled (e.g., driven) by switching circuit 112. Accordingly, switching circuit 112 may provide a control signal, such as a pulse-width modulated (PWM) signal to the switching device such that a frequency of the primary power signal provided to primary winding 132 may be controlled by switching circuit 112.

Switching circuit 112 is further configured to determine a line voltage measurement indicative of a line voltage provided by the AC power supply 102. For example, the line voltage measurement may be measured in Volts Alternating Current (VAC). In some embodiments, switching circuit 112 may measure (e.g., determine) the line voltage measurement across a standard range, such as from about 100 VAC to about 130 VAC, such as from 102 VAC to 132 VAC.

Switching circuit 112 is further configured to control a frequency of the primary power signal provided to the primary winding 132 based at least in part on the line voltage measurement. Switching circuit 112 may encode the line voltage measurement into the primary power signal provided to the primary winding 132 via frequency modulation. In some embodiments, switching circuit 112 may control the frequency of the primary power signal to correlate directly to the determined line voltage measurement. Switching circuit 112 may adjust the frequency of the primary power signal from a nominal frequency by an amount proportional to a line voltage offset, the line voltage offset indicative of a difference between the line voltage measurement and a nominal voltage. For instance, if the nominal voltage of the AC line voltage is 115 VAC and the line voltage measurement indicates an AC line voltage of 120 VAC, the frequency of the primary power signal (e.g., switching frequency) may be increased from a nominal frequency at 100 kilohertz (kHz) to 105 kHz such that the change in frequency (in kHz) is proportional to the line voltage offset (in VAC). In further embodiments, the change in frequency may be scaled to adjust the resolution.

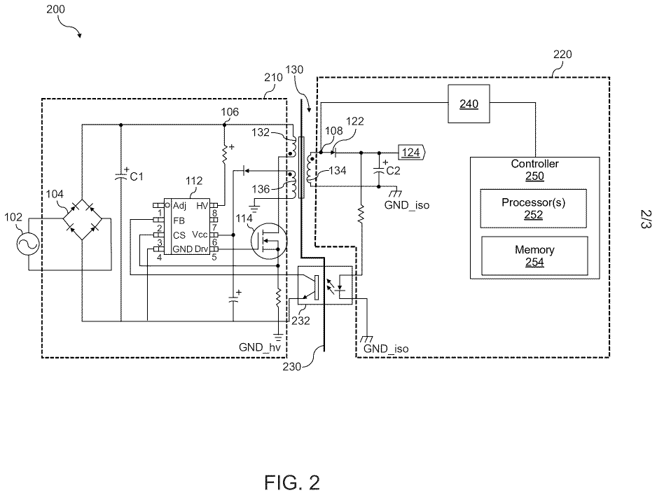

Referring now to FIG. 2, a circuit schematic of an example power supply system 200 is provided according to example embodiments of the present disclosure. Specifically, power supply system 200 may be a power supply system for an appliance such as a refrigerator, a dishwasher, a microwave oven, a cooktop, an oven, a washing machine, a dryer, a water heater, a water filter or purifier, an air conditioner, a space heater, or any other suitable household appliance.

Power supply system 200 is configured to receive power from a power supply 102, such as a residential power outlet or other power source. For example, power supply 102 may provide conventional 60 Hz, 120-volt or 240-volt alternating current (AC) to power supply system 200.

Power supply system 200 may include a non-isolated side 210 and an isolated side 220. As shown in FIG. 2, non-isolated side 210 of power supply system 100 is electrically coupled to AC power supply 102, while isolated side 220 of power supply system 100 is electrically isolated from the AC power supply 102. For example, power supply system 200 may include an isolation barrier 230 having one or more circuit isolation components, such as transformer 130 and/or ISO coupler 232, to electrically isolate the non-isolated side 210 from the isolated side 220.

In some embodiments, non-isolated side 210 may be defined as the high voltage side of power supply system 200 while isolated side 220 may be defined as the low voltage side of power supply system 200. For example, transformer 130 may be a step down transformer such that the voltage on the non-isolated side 210 (e.g., high voltage side) is greater than the voltage on the isolated side 220 (e.g., low voltage side).

As shown in FIG. 2, non-isolated side 210 of power supply system 200 may include a rectifier circuit 104 electrically coupled between AC power supply 102 and switching circuit 112. Although rectifier circuit 104 is depicted in FIG. 2 as a full-wave rectifier, those of ordinary skill in the art will understand that rectifier circuit 104 may be any suitable type/configuration rectifier without deviating from the scope of the present disclosure. Accordingly, switching circuit 112 may be coupled to AC power supply 102 via rectifier circuit 104. Specifically, switching circuit 112 may be coupled across rectifier circuit 104. For instance, both switching circuit 112 and rectifier circuit 104 may be coupled to measurement node 106 and the Non-isolated side ground (GND_HV). Switching circuit 112 may be configured to determine the line voltage measurement by sampling the voltage across rectifier circuit 104 (e.g., between measurement node 106 and the non-isolated side ground (GND_HV).

In some embodiments, non-isolated side 210 may further include a capacitor (C1) coupled between measurement node 106 and the non-isolated side ground (GND_HV) to, for instance, smooth the rectified voltage provided by rectifier circuit 104.

As shown in FIG. 2, power supply system 200 may be a switch mode power supply (SMPS) that utilizes an alternating current to direct current (AC/DC) converter. As such, switching circuit 112 may be an integrated circuit (IC) that may function as an AC/DC converter. For example, switching circuit 112 may provide a control signal, such as a pulse-width modulated (PWM) signal to switching device 114 to control the switching frequency of switching device 114 and thus the frequency of the primary power signal provided to primary winding 132 of transformer 130 in order to induce a direct current in the secondary winding 134 to be provided to the isolated side 220.

Specifically, switching circuit 112 may be configured to measure (e.g., determine) the AC line voltage measurement by sampling the voltage across rectifier circuit 104 (e.g., between measurement node 106 and the non-isolated side ground (GND_HV). For example, the line voltage measurement may be measured in Volts Alternating Current (VAC). In some embodiments, switching circuit 112 may measure (e.g., determine) the line voltage measurement across a standard range, such as from about 100 VAC to about 130 VAC, such as from 102 VAC to 132 VAC.

Switching circuit 112 is further configured to control a frequency of the primary power signal provided to the primary winding 132 based at least in part on the line voltage measurement. Specifically, switching circuit 112 may encode the line voltage measurement into the primary power signal provided to the primary winding 132 via frequency modulation. In some embodiments, switching circuit 112 may control the frequency of the primary power signal to correlate directly to the determined line voltage measurement. Switching circuit 112 may adjust the frequency of the primary power signal from a nominal frequency by an amount proportional to a line voltage offset, the line voltage offset indicative of a difference between the line voltage measurement and a nominal voltage. For instance, if the nominal voltage of the AC line voltage is 115 VAC and the line voltage measurement indicates an AC line voltage of 120 VAC, the frequency of the primary power signal (e.g., switching frequency) may be increased from a nominal frequency at 100 kilohertz (kHz) to 105 kHz such that the change in frequency (in kHz) is proportional to the line voltage offset (in VAC). In further embodiments, the change in frequency may be scaled to adjust the resolution.

Transformer 130 may include a primary winding 132 coupled to switching circuit 112 (e.g., via switching device 114) and a secondary winding 134 configured to provide a secondary power signal based at least in part on the primary power signal provided to the primary winding 132. In some embodiments, the secondary power signal provided by secondary winding 134 is configured to provide direct current (DC) power to the isolated side 220 of the power supply system 200. For example, isolated side 220 may include one or more diodes 122 and/or a capacitor (C2) configured to smooth the secondary power signal provided by secondary winding 134 such that components of the isolated side 220 (e.g., control system of appliance, controllers, etc.) may receive isolated DC power 124.

In addition to the primary winding 132 and secondary winding 134 as described above, transformer 130 may, in some embodiments, further include an auxiliary winding 136 coupled to the non-isolated side 210. Specifically, auxiliary winding 136 may be configured to provide power to switching circuit 112.

In some embodiments, power supply system 200 may further include additional circuit isolation components in addition to transformer 130. For instance, power supply system 200 may include an ISO coupler 232 configured to provide a feedback signal to switching circuit 112. For example, ISO coupler 232 may provide a feedback signal indicative of the voltage across the isolated side 120 output voltage rail (e.g., voltage between output of diode 122 and isolated side ground (GND_iso). Accordingly, switching circuit 217 may be configured to regulate the primary power signal provided to the primary winding 132 based on the feedback signal provided by ISO coupler 232.

In some embodiments, power supply system 200 may further include a controller 250. As shown, controller 250 may be provided on the isolated side 220 of power supply system 200 such that controller 250 is electrically isolated from AC power supply 102. Specifically, controller 250 may be electrically isolated from all components of the non-isolated side 210. As shown, controller 250 may be coupled to secondary winding 134. Specifically, controller 250 may be coupled to voltage node 108 (e.g., between diode 122 and secondary winding 134).

Controller 250 is configured to determine the line voltage measurement based at least in part on a frequency of the secondary power signal induced in the secondary winding. For example, controller 250 may receive a secondary power signal induced in secondary winding 134 of transformer 130 by a primary power signal provided to primary winding 132. As previously described, the line voltage measurement determined by switching circuit 112 may be encoded into the primary power signal provided to the primary winding 132. As such, controller 250 may be configured to decode the line voltage measurement from the secondary power signal. For instance, controller 250 may be configured to extract (e.g., decode) the line voltage measurement from the frequency data of the secondary power signal using Fast Fourier Transform (FFT) or other suitable extraction methods.

In some embodiments, controller 250 may be coupled to secondary winding 134 via signal processing circuit 240. Signal processing circuit 240 may be configured to condition secondary power signal (e.g., voltage clamping, filtering, etc.) such that the secondary power signal may be received by the controller 250.

In some embodiments, controller 250 may be configured to estimate an AC power consumption of the appliance based at least in part on the line voltage measurement extracted from the secondary power signal. For instance, a lookup table correlating a mode of the appliance with a baseline AC power consumption may be used to determine a baseline AC power consumption based on a current mode of the appliance. The baseline AC power consumption may then be modified based on an AC line voltage measurement determined while the appliance is operating in the current mode. Accordingly, the AC power consumption of the appliance of power supply system 200 may be determined based at least in part on the line voltage measurement.

Controller 250 may include one or more processor(s) 252. Processor(s) 252 may include any suitable processing device(s), such as one or more of a general or special purpose microprocessor, a microcontroller, an integrated circuit, an application specific integrated circuit (ASIC), a digital signal processor (DSP), a field-programmable gate array (FPGA), a logic device, one or more central processing units (CPUs), a graphics processing units (GPUs), processing units performing other specialized calculations, semiconductor devices, etc. In addition, processor(s) 252 are not necessarily restricted to a single element but may include any suitable number, type, and configuration of processing devices integrated in any suitable manner to facilitate appliance operation. In alternative embodiments, controller 250 may be constructed without using a microprocessor, e.g., using a combination of discrete analog or digital logic circuitry (such as switches, amplifiers, integrators, comparators, flip-flops, OR gates, and the like) to perform control functionality instead of relying upon software.

Controller 250 may further include, or be associated with, one or more memory devices 254. Memory devices 254 may include one or more memory elements or non-transitory computer-readable storage mediums, such as RAM, ROM, EEPROM, EPROM, flash memory devices, magnetic disks, or other suitable memory devices (including combinations thereof). Memory devices 254 may be a separate component from the processor(s) 252 or may be included onboard within the processor(s) 252. In addition, memory devices 254 can store information or data accessible by the one or more processors 252, including instructions that can be executed by the one or more processors 252. It should be appreciated that the instructions can be software written in any suitable programming language or can be implemented in hardware. Additionally, or alternatively, the instructions can be executed logically or virtually using separate threads on the one or more processors 252.

For example, controller 250 may be operable to execute programming instructions or micro-control code associated with an operating mode of appliance. In this regard, the instructions may be software or any set of instructions that when executed by the one or more processor(s) 252, cause the one or more processor(s) 252 to perform operations, such as running one or more software applications, displaying a user interface, receiving user input, processing user input, etc. Moreover, it should be noted that controller 250 as disclosed herein is capable of and may be operable to perform any methods, method steps, or portions of methods as disclosed herein. For example, in some embodiments, methods disclosed herein may be embodied in programming instructions stored in the memory devices 254 and executed by controller 250.

In some embodiments, memory devices 254 may also store data that can be retrieved, manipulated, created, or stored by the one or more processors 252 of controller 250. The data can include, for instance, data to facilitate performance of methods described herein. The data can be stored locally (e.g., on controller 250) in one or more databases or may be split up so that the data is stored in multiple locations. In addition, or alternatively, the one or more database(s) can be connected to controller 250 through any suitable network(s), such as through a high bandwidth local area network (LAN) or wide area network (WAN). In this regard, for example, controller 250 may further include a communication interface that may be used to communicate with one or more other component(s) of the appliance, controller 250, an external appliance controller, or any other suitable device, e.g., via any suitable communication lines or network(s) and using any suitable communication protocol.

Additionally and/or alternatively, controller 250 can include any suitable components for interfacing with one or more network(s), including for example, transmitters, receivers, ports, controllers, antennas, or other suitable components.

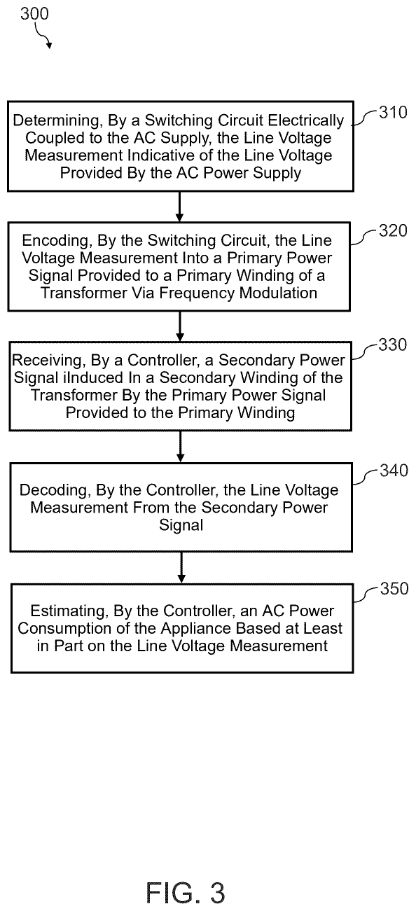

FIG. 3 provides an example method 300 for communicating a line voltage measurement indicative of a line voltage provided by an alternating current (AC) power supply in an appliance according to example embodiments of the present disclosure. Method 300 includes one or more steps that may be performed by a controller, such as controller 250 of FIG. 2. In some embodiments, various method steps of method 300 may be performed (e.g., in part or in whole) by controller 250. It is noted that the order of steps within method 300 is for illustrative purposes. Except as otherwise indicated, one or more steps in method 300 may be changed, rearranged, performed in a different order, or otherwise modified without deviating from the scope of the present disclosure. While method 300 is generally described with reference to power supply system 200 of FIG. 2 and power supply system 100 of FIG. 1, those of ordinary skill in the art will understand that method 300 may be performed or implemented by any suitable power supply system and/or appliance.

As shown in FIG. 3, method 300 may include, at step 310, determining, by a switching circuit electrically coupled to the AC power supply, the line voltage measurement indicative of the line voltage provided by the AC power supply. For example, switching circuit 217 is electrically coupled to AC power supply 102 (e.g., via rectifier circuit 104). Switching circuit 217 may determine a line voltage measurement indicative of the line voltage provided by the AC power supply 102.

Method 300 may further include, at step 320, encoding, by the switching circuit, the line voltage measurement into a primary power signal provided to a primary winding of a transformer via frequency modulation. For example, switching circuit 112 may control the switching frequency of switching device 114 to determine (e.g., adjust) the frequency of the primary power signal provided to primary winding 132 to indicate the line voltage measurement.

In some embodiments, method 300 may further include, at step 330, receiving, by a controller, a secondary power signal induced in a secondary winding of the transformer by the primary power signal provided to the primary winding. For example, controller 250 may receive the secondary power signal induced in the secondary winding 134 of transformer 130 by the primary power signal provided to the primary winding 132.

In some embodiments, method 300 may further include, at step 340, decoding, by the controller, the line voltage measurement from the secondary power signal. For example, controller 250 may decode the line voltage measurement from the secondary power signal by using Fast Fourier Transform (FFT) or other suitable extraction methods.

In some embodiments, method 300 may further include, at step 350, estimating, by the controller, an AC power consumption of the appliance based at least in part on the line voltage measurement. For example, controller 250 may be configured to estimate an AC power consumption of the appliance of the power supply system 100, 200 based at least in part on the line voltage measurement decoded from the secondary power signal.

One example aspect of the present disclosure is directed to a power supply system for an appliance. The power supply system includes a switching circuit electrically coupled to an alternating current (AC) power supply, the switching circuit configured to determine a line voltage measurement indicative of a line voltage provided by the AC power supply. The power supply system further includes a transformer. The transformer includes a primary winding coupled to the switching circuit. The transformer further includes a secondary winding configured to provide a secondary power signal based at least in part on a primary power signal provided to the primary winding. The switching circuit is configured to control a frequency of the primary power signal provided to the primary winding based at least in part on the line voltage measurement.

In some examples, the power supply system further includes a rectifier circuit electrically coupled between the AC power supply and the switching circuit. The line voltage measurement is indicative of a voltage across the rectifier circuit.

In some examples, a controller is coupled to the secondary winding, the controller configured to determine the line voltage measurement based at least in part on a frequency of the secondary power signal induced in the secondary winding.

In some examples, the controller is electrically isolated from the AC power supply.

In some examples, the controller is coupled to the secondary winding via a signal processing circuit.

In some examples, the controller is configured to estimate an AC power consumption of the appliance based at least in part on the line voltage measurement.

In some examples, the switching circuit is configured to adjust the frequency of the primary power signal from a nominal frequency by an amount proportional to a line voltage offset, the line voltage offset indicative of a difference between the line voltage measurement and a nominal voltage.

Another example aspect of the present disclosure is directed to a power supply system for an appliance. The power supply system includes a non-isolated side comprising a switching circuit electrically coupled to an alternating current (AC) power supply, the switching circuit configured to determine a line voltage measurement indicative of a line voltage provided by the AC power supply. The power supply system further includes an isolated side electrically isolated from the AC power supply. The power supply system further includes a transformer. The transformer includes a primary winding coupled to the non-isolated side. The transformer further includes a secondary winding configured to provide a secondary power signal to the isolated side based at least in part on a primary power signal provided to the primary winding. The switching circuit is configured to control a frequency of the primary power signal provided to the primary winding based at least in part on the line voltage measurement.

In some examples, the non-isolated side further includes a rectifier circuit electrically coupled between the AC power supply and the switching circuit. The line voltage measurement is indicative of a voltage across the rectifier circuit.

In some examples, the isolated side includes a controller coupled to the secondary winding, the controller configured to determine the line voltage measurement based at least in part on a frequency of the secondary power signal induced in the secondary winding.

In some examples, the isolated side further includes a signal processing circuit, the controller coupled to the secondary winding via the signal processing circuit.

In some examples, the controller is configured to estimate an AC power consumption of the appliance based at least in part on the line voltage measurement.

In some examples, the switching circuit is configured to adjust the frequency of the primary power signal from a nominal frequency by an amount proportional to a line voltage offset, the line voltage offset indicative of a difference between the line voltage measurement and a nominal voltage.

In some examples, the secondary power signal is configured to provide direct current (DC) power to the isolated side of the power supply system.

Another example aspect of the present disclosure is directed to a method for communicating a line voltage measurement indicative of a line voltage provided by an alternating current (AC) power supply in an appliance. The method includes determining, by a switching circuit electrically coupled to the AC power supply, the line voltage measurement indicative of the line voltage provided by the AC power supply. The method further includes encoding, by the switching circuit, the line voltage measurement into a primary power signal provided to a primary winding of a transformer via frequency modulation.

In some examples, the line voltage measurement is indicative of a voltage across a rectifier circuit, the rectifier circuit coupled between the AC power supply and the switching circuit.

In some examples, the method further includes receiving, by a controller, a secondary power signal induced in a secondary winding of the transformer by the primary power signal provided to the primary winding; and decoding, by the controller, the line voltage measurement from the secondary power signal.

In some examples, the controller is electrically isolated from the AC power supply.

In some examples, the method further includes estimating, by the controller, an AC power consumption of the appliance based at least in part on the line voltage measurement.

In some examples, encoding, by the switching circuit, the line voltage measurement into the primary power signal includes adjusting a frequency of the primary power signal from a nominal frequency by an amount proportional to a line voltage offset, the line voltage offset indicative of a difference between the line voltage measurement and a nominal voltage.

Although specific features of various embodiments may be shown in some drawings and not in others, this is for convenience only. In accordance with the principles of the present disclosure, any feature of a drawing can be referenced and/or claimed in combination with any feature of any other drawing.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power supply system for an appliance, comprising:
a switching circuit electrically coupled to an alternating current (AC) power supply, the switching circuit configured to determine a line voltage measurement indicative of a line voltage provided by the AC power supply; and
a transformer comprising:
a primary winding coupled to the switching circuit; and
a secondary winding configured to provide a secondary power signal based at least in part on a primary power signal provided to the primary winding,
wherein the switching circuit is configured to control a frequency of the primary power signal provided to the primary winding based at least in part on the line voltage measurement.

2. The power supply system of claim 1, further comprising:
a rectifier circuit electrically coupled between the AC power supply and the switching circuit,
wherein the line voltage measurement is indicative of a voltage across the rectifier circuit.

3. The power supply system of claim 1, wherein a controller is coupled to the secondary winding, the controller configured to determine the line voltage measurement based at least in part on a frequency of the secondary power signal induced in the secondary winding.

4. The power supply system of claim 3, wherein the controller is electrically isolated from the AC power supply.

5. The power supply system of claim 4, wherein the controller is coupled to the secondary winding via a signal processing circuit.

6. The power supply system of claim 3, wherein the controller is configured to estimate an AC power consumption of the appliance based at least in part on the line voltage measurement.

7. The power supply system of claim 1, wherein the switching circuit is configured to adjust the frequency of the primary power signal from a nominal frequency by an amount proportional to a line voltage offset, the line voltage offset indicative of a difference between the line voltage measurement and a nominal voltage.

8. A power supply system for an appliance, comprising:
a non-isolated side comprising a switching circuit electrically coupled to an alternating current (AC) power supply, the switching circuit configured to determine a line voltage measurement indicative of a line voltage provided by the AC power supply;
an isolated side electrically isolated from the AC power supply; and
a transformer comprising:
a primary winding coupled to the non-isolated side; and
a secondary winding configured to provide a secondary power signal to the isolated side based at least in part on a primary power signal provided to the primary winding,
wherein the switching circuit is configured to control a frequency of the primary power signal provided to the primary winding based at least in part on the line voltage measurement.

9. The power supply system of claim 8, wherein the non-isolated side further comprises:
a rectifier circuit electrically coupled between the AC power supply and the switching circuit,
wherein the line voltage measurement is indicative of a voltage across the rectifier circuit.

10. The power supply system of claim 8, wherein the isolated side comprises:
a controller coupled to the secondary winding, the controller configured to determine the line voltage measurement based at least in part on a frequency of the secondary power signal induced in the secondary winding.

11. The power supply system of claim 10, wherein the isolated side further comprises:
a signal processing circuit, the controller coupled to the secondary winding via the signal processing circuit.

12. The power supply system of claim 10, wherein the controller is configured to estimate an AC power consumption of the appliance based at least in part on the line voltage measurement.

13. The power supply system of claim 8, wherein the switching circuit is configured to adjust the frequency of the primary power signal from a nominal frequency by an amount proportional to a line voltage offset, the line voltage offset indicative of a difference between the line voltage measurement and a nominal voltage.

14. The power supply system of claim 8, wherein the secondary power signal is configured to provide direct current (DC) power to the isolated side of the power supply system.

15. A method for communicating a line voltage measurement indicative of a line voltage provided by an alternating current (AC) power supply in an appliance, the method comprising:
determining, by a switching circuit electrically coupled to the AC power supply, the line voltage measurement indicative of the line voltage provided by the AC power supply; and
encoding, by the switching circuit, the line voltage measurement into a primary power signal provided to a primary winding of a transformer via frequency modulation.

16. The method of claim 15, wherein the line voltage measurement is indicative of a voltage across a rectifier circuit, the rectifier circuit coupled between the AC power supply and the switching circuit.

17. The method of claim 15, further comprising:
receiving, by a controller, a secondary power signal induced in a secondary winding of the transformer by the primary power signal provided to the primary winding; and
decoding, by the controller, the line voltage measurement from the secondary power signal.

18. The method of claim 17, wherein the controller is electrically isolated from the AC power supply.

19. The method of claim 17, further comprising:
estimating, by the controller, an AC power consumption of the appliance based at least in part on the line voltage measurement.

20. The method of claim 15, wherein encoding, by the switching circuit, the line voltage measurement into the primary power signal comprises:
adjusting a frequency of the primary power signal from a nominal frequency by an amount proportional to a line voltage offset, the line voltage offset indicative of a difference between the line voltage measurement and a nominal voltage.
